(19) United States
(12) Patent Application Publication
(10) Pub. No.: US 2026/0113940 A1
(43) Pub. Date: Apr. 23, 2026

(54) SEMICONDUCTOR MEMORY DEVICE AND METHOD OF MANUFACTURING SEMICONDUCTOR MEMORY DEVICE

(71) Applicant: SK hynix Inc., Icheon-si Gyeonggi-do (KR)

(72) Inventor: Jae Hyun HAN, Icheon-si Gyeonggi-do (KR)

(73) Assignee: SK hynix Inc., Icheon-si Gyeonggi-do (KR)

(21) Appl. No.: 19/170,960

(22) Filed: Apr. 4, 2025

(30) Foreign Application Priority Data
Oct. 17, 2024 (KR) 10-2024-0142154

(51) Int. Cl. H10B 43/27; H10B 43/10; H10B 43/35; H10D 30/01; H10D 30/69; H10D 64/68

(52) U.S. Cl. CPC H10B 43/27; H10B 43/10; H10B 43/35; H10D 30/0413; H10D 30/693; H10D 64/687

(57) ABSTRACT

A semiconductor memory device includes a gate array including a plurality of conductive layers alternately stacked with a plurality of interlayer insulating structures in a stack direction, a cell pillar extending through the gate array in the stack direction, and a porous layer surrounding the cell pillar, wherein an opening or an air gap is formed between a first section of a first interlayer insulating structure of the plurality of interlayer insulating structures and a second section of the first interlayer insulating structure, the opening surrounding the porous layer disposed between the first section and the second section.

### CROSS-REFERENCE TO RELATED APPLICATION

The present application claims priority under 35 U.S.C. § 119(a) to Korean patent application number 10-2024-0142154 filed on Oct. 17, 2024, in the Korean Intellectual Property Office, the entire contents of which application is incorporated herein by reference.

### BACKGROUND

### 1. Technical Field

The present application generally relates to a semiconductor memory device and a method of manufacturing the semiconductor memory device, including but not limited to a three-dimensional (3D) semiconductor memory device and a method of manufacturing the 3D semiconductor memory device.

### 2. Related Art

A semiconductor memory device may be found not only in small-sized electronic devices but also in electronic systems in various fields such as vehicles, medical appliances, and data centers. Accordingly, semiconductor memory devices are in increasing demand.

Semiconductor memory devices include memory cells that store data. Because three-dimensional (3D) semiconductor memory devices include a plurality of memory cells arranged in three dimensions, 3D semiconductor memory devices are more advantageous for large capacity compared to a two-dimensional (2D) semiconductor memory device.

The degree of integration of memory cells in the 3D semiconductor memory device may be improved by increasing the number of stacks of memory cells. When the number of memory cells that are stacked increases, the height of a stacked body including conductive layers connected to the memory cells increases. In order to decrease the difficulty of an etching process as the height of the stacked body increase, the thickness of each conductive layer is decreased. When the thickness of each conductive layer is decreased, the operation speed of the semiconductor memory device may deteriorate due to an increase in capacitance between consecutive conductive layers.

### SUMMARY

A semiconductor memory device may include a gate array including a plurality of conductive layers spaced apart from each other in a stack direction, a channel pillar extending in the stack direction through the plurality of conductive layers, a tunnel insulating layer between the channel pillar and the gate array, a data storage layer between the tunnel insulating layer and the gate array, a porous layer between the data storage layer and the gate array, and an insulating molding structure including a plurality of interlayer insulating structures, the plurality of interlayer insulating structures alternately arranged with the plurality of conductive layers in the stack direction, wherein a plurality of air gaps is formed within the plurality of interlayer insulating structures, respectively, and adjacent to the porous layer.

A semiconductor memory device may include a first gate array including a plurality of first conductive layers spaced apart from each other in a stack direction, a second gate array separated from the first gate array by a gate separation structure, the second gate array including a plurality of second conductive layers spaced apart from each other in the stack direction, a plurality of first cell pillars extending in the stack direction through the plurality of first conductive layers, a plurality of second cell pillars extending in the stack direction through a plurality of second conductive layers, an insulating molding structure including a plurality of first interlayer insulating structures and a plurality of second interlayer insulating structures, the plurality of first interlayer insulating structures alternately arranged with the plurality of first conductive layers in the stack direction, the plurality of second interlayer insulating structures alternately arranged with the plurality of second conductive layers in the stack direction, a plurality of porous layers corresponding to the plurality of first cell pillars and the plurality of second cell pillars, wherein an outer wall of each of the plurality of first cell pillars and the plurality of second cell pillars is surrounded by a corresponding porous layer of the plurality of porous layers, and wherein a plurality of air gaps is formed within the insulating molding structure and adjacent to the plurality of porous layers.

A method of manufacturing a semiconductor memory device may include forming a stacked body including a plurality of conductive layers alternately arranged with a plurality of interlayer insulating structures in a stack direction and surrounding an insulating pillar extending in the stack direction, opening a hole in the stacked body by removing the insulating pillar, forming a porous layer along a sidewall of the stacked body, the sidewall adjacent to the hole, forming a plurality of air gaps within the plurality of interlayer insulating structures, respectively, and adjacent to the porous layer by removing, through the hole, sections of the plurality of interlayer insulating structures adjacent to the porous layer, and forming a cell pillar in the hole and surrounded by the porous layer.

A semiconductor memory device may include a gate array including a plurality of conductive layers alternately stacked with a plurality of interlayer insulating structures in a stack direction; a cell pillar extending through the gate array in the stack direction; and a porous layer surrounding the cell pillar, wherein an opening is formed between a first section of a first interlayer insulating structure of the plurality of interlayer insulating structures and a second section of the first interlayer insulating structure, the opening surrounding the porous layer disposed between the first section and the second section.

### BRIEF DESCRIPTION OF THE DRAWINGS

FIG. 1 is a block diagram illustrating an electronic system including a semiconductor memory device according to an embodiment of the present disclosure.

FIG. 2A and FIG. 2B are views illustrating a semiconductor memory device according to an embodiment of the present disclosure.

FIG. 3A and FIG. 3B are cross-sectional views of a semiconductor memory device taken at a level of a word line according to an embodiment of the present disclosure.

FIG. 4A to FIG. 4F are cross-sectional views illustrating elements formed utilizing a method of manufacturing a semiconductor memory device according to an embodiment of the present disclosure.

FIG. 5A and FIG. 5B are enlarged sectional views of the area AR1 of FIG. 4E.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

Terms such as “first” and “second” are used to distinguish between various elements and do not imply size, order, priority, quantity, or importance of the elements. For example, a first element may be named as a second element in one example, and the second element may be named as a first element in another example.

When one component is identified as “connected” to another component, the components may be connected directly or through an intervening component between the components. When two components are identified as “directly connected,” one component is directly connected to the other component without an intervening component between the two components.

Terms such as “bottom,” “over,” “on,” “sidewall,” “lower,” “higher,” “high,” “front,” “rear,” “left,” “right,” “column,” “row,” and other terms implying relative spatial relationship or orientation are utilized only for the purpose of ease of description or reference to a drawing and are not otherwise limiting.

The cross-hatching throughout the figures illustrates corresponding or similar areas between the figures rather than indicating the materials associated with the areas.

The present disclosure is directed to embodiments of a semiconductor memory device having improved operation speed and methods of manufacturing the semiconductor memory device.

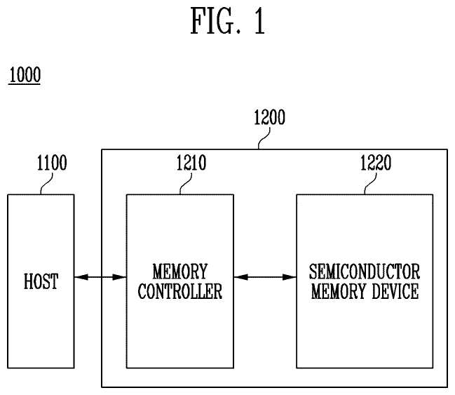

FIG. 1 is a block diagram illustrating an electronic system including a semiconductor memory device according to an embodiment of the present disclosure.

Referring to FIG. 1, an electronic system 1000 may be a computing system, a medical device, a communication device, a wearable device, a memory system, or the like. The electronic system 1000 includes a host 1100 and a storage device 1200.

The host 1100 stores data in the storage device 1200 and reads data stored in the storage device 1200 based on an interface. The interface may include a double data rate (DDR) interface, a universal serial bus (USB) interface, a multimedia card (MMC) interface, an embedded MMC (eMMC) interface, a peripheral component interconnection (PCI) interface, a PCI-express (PCI-E) interface, an advanced technology attachment (ATA) interface, a serial-ATA (SATA) interface, a parallel-ATA (PATA) interface, a small computer system interface (SCSI), an enhanced small disk interface (ESDI), an integrated drive electronics (IDE) interface, a Firewire interface, a universal flash storage (UFS) interface, or a nonvolatile memory express (NVMe) interface, or a combination of two or more interfaces.

The storage device 1200 includes a memory controller 1210 and a semiconductor memory device 1220. The storage device 1200 may be a storage medium such as a solid state drive (SSD) or a universal serial bus (USB) memory.

The memory controller 1210 stores data in the semiconductor memory device 1220 and reads data stored in the semiconductor memory device 1220 under control of the host 1100.

The semiconductor memory device 1220 includes one memory chip or a plurality of memory chips. The semiconductor memory device 1220 stores data or outputs stored data under control of the memory controller 1210.

The semiconductor memory device 1220 may be a nonvolatile memory device. The semiconductor memory device 1220 includes a memory cell array and a peripheral circuit that controls operation of the memory cell array. The memory cell array includes a plurality of memory cells. Each memory cell may be a nonvolatile memory cell. In an embodiment, each memory cell is a NAND flash memory cell. The present disclosure is described based on an example of the semiconductor memory device including NAND flash memory cells, although the present disclosure is not limited to this example. Alternatively, each memory cell may be implemented as a ferroelectric memory cell, a variable-resistance memory cell, or the like.

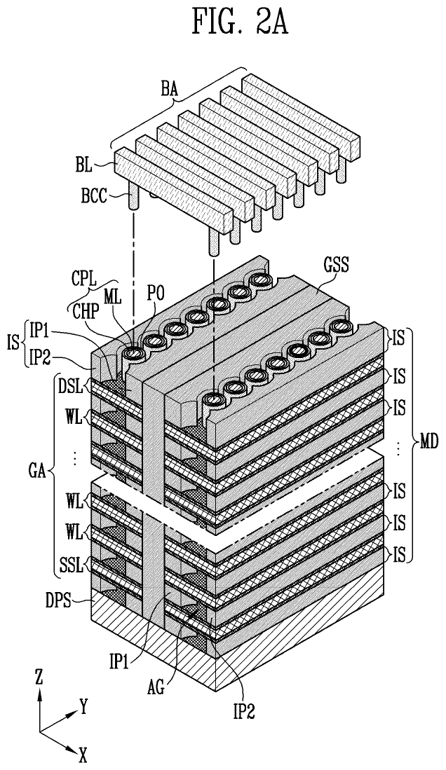

FIG. 2A and FIG. 2B are views illustrating a semiconductor memory device according to an embodiment of the present disclosure.

Referring to FIG. 2A, the semiconductor memory device includes a doped semiconductor structure DPS, a bit line array BA, a plurality of gate arrays GA, an insulating molding structure MD, a plurality of porous layers PO, a plurality of cell pillars CPL, and a plurality of air gaps AG. The plurality of gate arrays GA and the insulating molding structure MD may be arranged between the doped semiconductor structure DPS and the bit line array BA.

Each of the gate arrays GA includes a plurality of conductive layers SSL, WL, and DSL. The plurality of conductive layers SSL, WL, and DSL extend along an XY plane and are stacked in a Z direction. The Z direction is referred to as a stack direction. The plurality of conductive layers SSL, WL, and DSL are spaced apart in the Z direction. The plurality of conductive layers SSL, WL, and DSL includes at least one source select line SSL, at least one drain select line DSL, and a plurality of word lines WL disposed in the Z direction between the source select line SSL and the drain select line DSL. The source select line SSL is connected to a gate electrode of a source select transistor, the drain select line DSL is connected to a gate electrode of a drain select transistor, and the plurality of word lines are connected to a plurality of gates of a plurality of memory cells, respectively. Each of the plurality of conductive layers SSL, WL, and DSL includes various conductive materials such as a doped semiconductor layer and a metal layer. The doped semiconductor layer may include a doped silicon layer. The metal layer may include tungsten, copper, molybdenum, or the like. Each of the plurality of conductive layers SSL, WL, and DSL further includes a metal barrier layer. The metal barrier layer may include a metal nitride layer, which may include titanium nitride, tantalum nitride, or the like. The metal barrier layer may include a dual layer of titanium and titanium nitride.

A gate separation structure GSS extends in the Z direction through the plurality of conductive layers SSL, WL, and DSL. The plurality of conductive layers SSL, WL, and DSL are separated into a plurality of gate arrays GA by the gate separation structure GSS. In an embodiment, the gate separation structure GSS includes an insulating material. In an embodiment, the gate separation structure GSS further includes a conductive material, a semiconductor material, or layers corresponding to a dual-layer or multi-layer structure in addition to the insulating material. Although not illustrated in the drawings, the insulating material of the gate separation structure GSS may be formed to cover the plurality of conductive layers SSL, WL, and DSL, thus insulating the plurality of conductive layers SSL, WL, and DSL from other conductive structures.

The plurality of porous layers PO and the plurality of cell pillars CPL extend in the Z direction through the plurality of conductive layers SSL, WL, and DSL. The plurality of porous layers PO and the plurality of cell pillars CPL are arranged in a plurality of columns and a plurality of rows. In an embodiment, one row including porous layers and cell pillars arranged in a Y direction extends through the plurality of conductive layers SSL, WL, and DSL of each gate array GA. Embodiments of the present disclosure are not limited to this example, and two or more rows of porous layers and cell pillars may extend through each gate array GA.

The insulating molding structure MD includes a plurality of interlayer insulating structures IS. The plurality of interlayer insulating structures IS are alternately arranged or stacked with the plurality of conductive layers SSL, WL, and DSL in the Z direction. Each of the interlayer insulating structures IS includes a first insulating pattern IP1 and a second insulating pattern IP2. Thus, each of the interlayer insulating structures IS includes a first section IP1 and a second section IP2. The first insulating pattern IP1 is spaced apart from the second insulating pattern IP2, with at least one row of porous layers and cell pillars disposed between the first insulating pattern IP1 and the second insulating pattern IP2. The first insulating pattern IP1 and the second insulating pattern IP2 may each include an insulating material such as a silicon oxide layer or a silicon oxynitride layer.

The plurality of porous layers PO correspond to the plurality of cell pillars CPL, respectively. Each of the plurality of porous layers PO corresponds to a different one of the plurality of cell pillars CPL. Each of the porous layers PO surrounds an outer wall of the corresponding cell pillar CPL. The outer surface of the outer wall of the cell pillar CPL faces the gate array GA and the insulating molding structure MD. Thus, the porous layer PO is disposed between the corresponding cell pillar CPL and the gate array GA.

FIG. 2B is a view illustrating the porous layer PO and the cell pillar CPL such as shown in FIG. 2A.

Referring to FIG. 2A and FIG. 2B, the cell pillar CPL includes a channel pillar CHP, a tunnel insulating layer TI, a data storage layer DS, and a blocking insulating layer BI.

The channel pillar CHP extends in the Z direction through the plurality of conductive layers SSL, WL, and DSL. The channel pillar CHP includes a channel layer CLL. The channel layer CLL may include a semiconductor material such as silicon (Si), germanium (Ge), or a combination thereof, which may form a channel region of a memory cell string. The channel layer CLL may be formed in a tubular shape. In this example, the channel pillar CHP includes a core insulating layer CO and a capping pattern CAP arranged in a central region of a tubular structure of the channel layer CLL. The capping pattern CAP may include a semiconductor layer doped with conductive impurities. The conductive impurities may include either n-type impurities or n-type impurities and p-type impurities. In an embodiment, the capping pattern CAP may include n-type doped silicon including n-type impurities as majority carriers. The sidewall of the channel layer CLL is surrounded by the porous layer PO.

The tunnel insulating layer TI is disposed between the channel layer CLL and the porous layer PO. The tunnel insulating layer TI may include oxide such as silicon dioxide (SiO₂).

The data storage layer DS is disposed between the tunnel insulating layer TI and the porous layer PO. The data storage layer DS includes a material layer that stores data changed through Fowler-Nordheim tunneling, for example. In an embodiment, the data storage layer DS includes a charge trap insulating layer or an insulating layer including conductive nanodots. The charge trap insulating layer may include a silicon nitride layer.

The blocking insulating layer BI is disposed between the data storage layer DS and the porous layer PO. The blocking insulating layer BI may include oxide, such as silicon dioxide (SiO₂) and a high dielectric insulating material having a dielectric constant higher than a dielectric constant of silicon dioxide. The high dielectric insulating material may include an aluminum oxide layer, a hafnium oxide layer, or the like.

The porous layer PO has an etch selectivity relative to the interlayer insulating structure IS. In an embodiment, the porous layer PO may include a Metal-Organic Framework (MOF). The metal-organic framework includes a porous coordination polymer formed by the coordination bonding of organic ligands to metal ions. The metal-organic framework may have a crystalline polymer structure, in which nanometer-sized fine pores are regularly arranged, by regular bonding between metal ions and organic ligands. The central metal of the metal-organic framework may include Zn²⁺, Zr⁴⁺, Al³⁺, and the like. The organic ligands of the metal-organic framework may include 2-methylimidazole, 2-aminoterephthalic acid, 1,3,5-benzenetricarboxylate, and the like.

The porous layer PO functions as a blocking insulating layer and pores in the porous layer PO are empty or filled with various insulating materials.

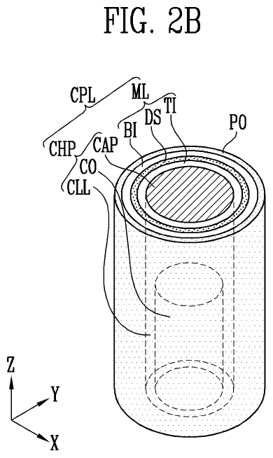

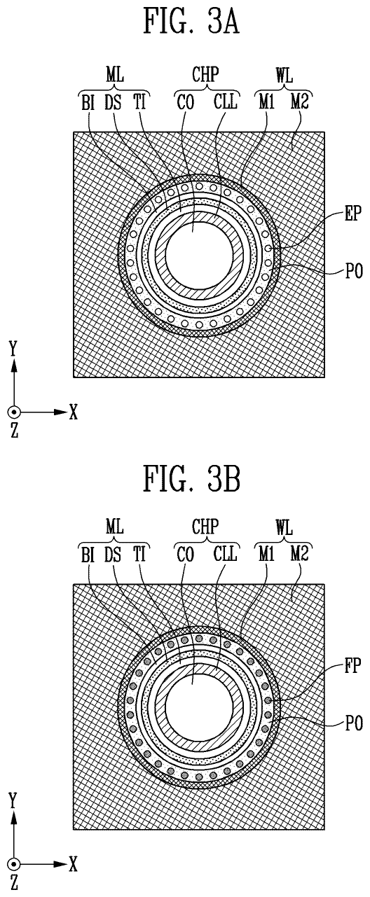

FIG. 3A and FIG. 3B are cross-sectional views of a semiconductor memory device at a level of a word line, for example, as shown in FIG. 2A according to an embodiment of the present disclosure.

Referring to FIG. 3A and FIG. 3B, a channel pillar CHP including a channel layer CLL and a core insulating layer CO is surrounded by a memory layer ML. The tunnel insulating layer TI of the memory layer ML surrounds the channel layer CLL, the data storage layer DS of the memory layer ML surrounds the tunnel insulating layer TI, and the blocking insulating layer BI of the memory layer ML surrounds the data storage layer DS.

The porous layer PO surrounds the memory layer ML. In the example of FIG. 3A, empty pores EP or holes are formed in the porous layer PO. In the example of FIG. 3B, pores FP or holes are formed in the porous layer PO, where the pores FP or holes are filled with an insulating material. The porous layer PO including the empty pores EP has a different dielectric constant from the porous layer PO including the pores FP filled with the insulating material. In an embodiment, the insulating material filling the pores has a dielectric constant higher than a dielectric constant of the blocking insulating layer BI. For example, the blocking insulating layer BI may include silicon dioxide, and the insulating material filled within the pores may include an aluminum oxide layer, a hafnium oxide layer, or the like, which has a dielectric constant higher than a dielectric constant of silicon dioxide.

The porous layer PO is surrounded by a conductive layer, such as a word line WL. In an embodiment, the conductive layer, such as the word line WL, includes a metal barrier layer M1 and a metal layer M2 such as tungsten or molybdenum. The present disclosure is not limited to these examples, and the conductive layer, such as the word line WL, may be made of a single metal or may include a doped semiconductor layer.

According to an embodiment, when a separate high-dielectric insulating layer is not disposed between the conductive layer, such as the word line WL, and the porous layer PO, the pores of the porous layer PO are filled with a high dielectric insulating material such that the porous layer PO is a high dielectric blocking insulating layer.

Referring to FIG. 2A and FIG. 2B, a source select transistor is formed at an intersection between the source select line SSL and the channel layer CLL, a drain select transistor is formed at an intersection between the drain select line DSL and the channel layer CLL, and a plurality of memory cells are formed at intersections between a plurality of word lines WL and the channel layer CLL. The source select transistor, the plurality of memory cells, and the drain select transistor are connected in series by the channel layer CLL of the channel pillar CHP to form a memory cell string.

The channel pillar CHP is connected to the doped semiconductor structure DPS and the bit line array BA.

The doped semiconductor structure DPS includes a doped semiconductor layer including at least one layer. The doped semiconductor layer of the doped semiconductor structure DPS may include n-type impurities or p-type impurities. In an embodiment, the doped semiconductor structure DPS includes a first conductive doped semiconductor layer including n-type impurities as majority carriers, a second conductive doped semiconductor layer including p-type impurities as majority carriers, or semiconductor layers corresponding to a dual-layer or multi-layer structure including the first conductive doped semiconductor layer and the second conductive doped semiconductor layer. The first conductive doped semiconductor layer functions as a common source region, and the second conductive doped semiconductor layer functions as a well region. The common source region of the doped semiconductor structure DPS directly contacts the sidewall or bottom surface of the channel pillar CHP. In an embodiment, the channel layer CLL of the channel pillar CHP extends into the doped semiconductor structure DPS to contact the doped semiconductor structure DPS.

The bit line array BA includes a plurality of bit lines BL. The plurality of bit lines BL disposed on an XY plane extend in a direction intersecting the gate separation structure GSS and are spaced apart from each other in the direction in which the gate separation structure GSS extends. In an embodiment, the plurality of bit lines BL has a length extending in the X direction and are spaced apart from each other in the Y direction. Each of the bit lines BL is electrically connected to the capping pattern CAP of a corresponding channel pillar CHP via a bit line connection structure BCC.

Although not illustrated in the drawings, the peripheral circuit structure of the semiconductor memory device may be arranged adjacent to the doped semiconductor structure DPS or the bit line array BA. In an embodiment, the cell array structure including the memory cell string is formed over the peripheral circuit structure. In an embodiment, the cell array structure is formed separately from the peripheral circuit structure and is electrically connected to the peripheral circuit structure by a bonding process.

The source select line SSL is the conductive layer nearest to the doped semiconductor structure DPS, and the drain select line DSL the conductive layer nearest to the bit line array BA. The plurality of interlayer insulating structures IS of the insulating molding structure MD includes a lower interlayer insulating structure IS disposed between the source select line SSL and the doped semiconductor structure DPS, an upper interlayer insulating structure IS disposed between the drain select line DSL and the bit line array BA, and intermediate interlayer insulating structures IS disposed between the source select line SSL, the plurality of word lines WL, and the drain select line DSL.

A plurality of air gaps AG are formed within each of the plurality of interlayer insulating structures IS. An air gap AG is formed between each of the plurality of porous layers PO and a corresponding first insulating pattern IP1 of one the plurality of interlayer insulating structures IS and between each of the plurality of porous layers PO and a corresponding second insulating pattern IP2 of one the plurality of interlayer insulating structures IS. Accordingly, the porous layers PO are spaced apart from the interlayer insulating structure IS of the insulating molding structure MD by the plurality of air gaps AG. The air gaps AG extend to areas between consecutive cell pillars CPL. The air gaps AG may be formed by etching the plurality of interlayer insulating structures IS through the pores of the porous layer PO. As a result, the plurality of air gaps AG are closer to the plurality of cell pillars CHP than to the gate separation structure GSS. The air gaps AG of a single interlayer insulating structure IS may comprise a single contiguous opening, such as shown in the example of FIG. 2A. For example, the opening is formed between a first section IP1 of a first interlayer insulating structure and a second section IP2 of the first interlayer insulating structure, and the opening surrounds the porous layer PO disposed between the first section IP1 and the second section IP2.

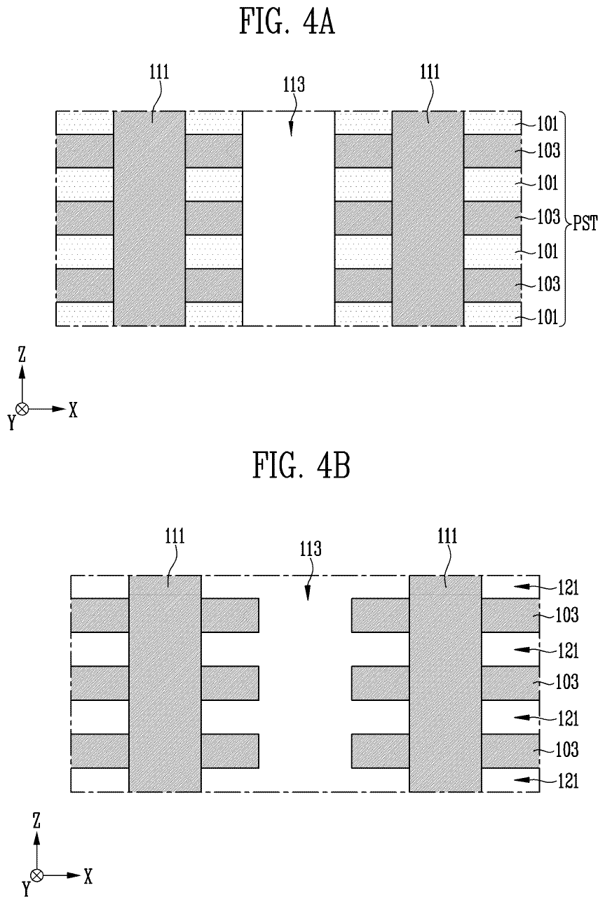

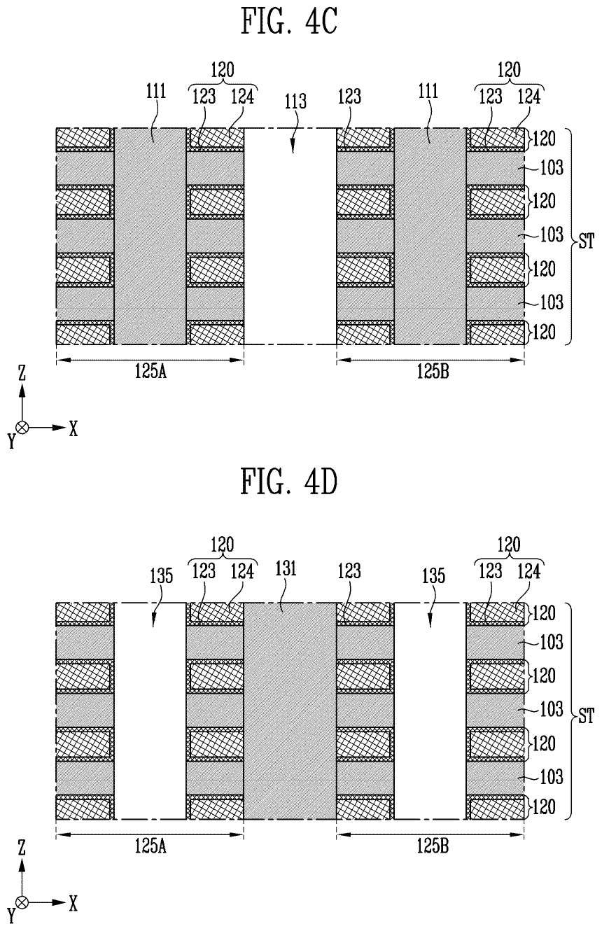

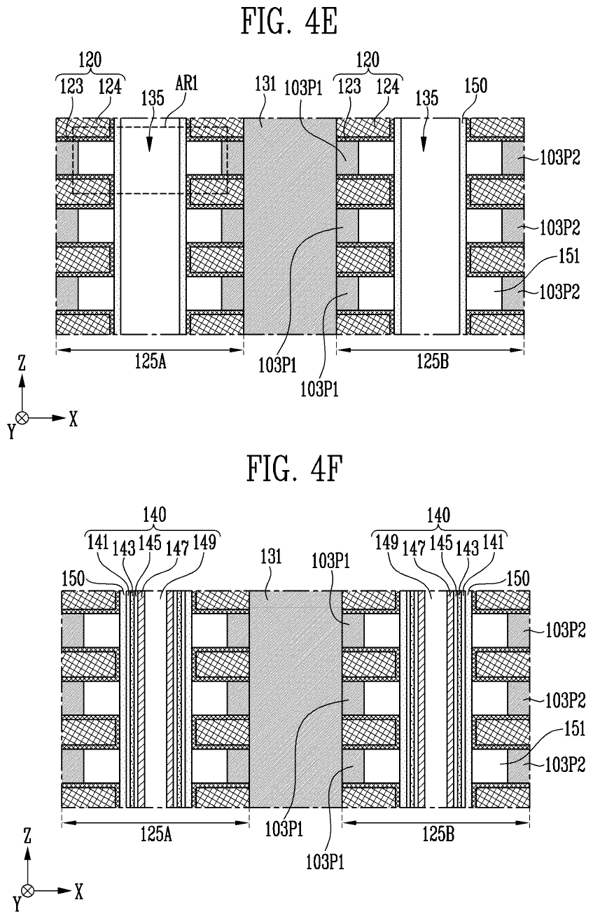

A method of manufacturing the semiconductor memory device illustrated in FIG. 2A and FIG. 2B is described with reference to FIG. 4A to FIG. 4F.

FIG. 4A to FIG. 4F are cross-sectional views illustrating elements formed utilizing a method of manufacturing a semiconductor memory device according to an embodiment of the present disclosure. The cross-sectional views are taken in an X direction through a center of two consecutive cell pillars of the semiconductor memory device illustrated in FIG. 2A.

Referring to FIG. 4A, a preliminary stacked body PST surrounding a plurality of insulating pillars 111 is formed over a lower structure (not illustrated). In an embodiment, the lower structure may include the doped semiconductor structure DPS such as illustrated in FIG. 2A. In an embodiment, the lower structure may include a preliminary doped semiconductor structure in which a source sacrificial structure is embedded. The source sacrificial structure may be replaced with the doped semiconductor structure DPS, illustrated in FIG. 2A, in a subsequent process.

The plurality of insulating pillars 111 are arranged in a plurality of columns and a plurality of rows along an XY plane. Forming the preliminary stacked body PST surrounding the plurality of insulating pillars 111 includes alternately arranging a plurality of sacrificial layers 101 with a plurality of interlayer insulating structures 103 in a Z direction over the lower structure, forming a plurality of holes passing through the plurality of sacrificial layers 101 and the plurality of interlayer insulating structures 103, and filling the plurality of holes with an insulating material.

Each of the plurality of interlayer insulating structures 103 may include an insulating material such as a silicon oxide layer and a silicon oxynitride layer. The plurality of sacrificial layers 101 has an etch selectivity relative to the plurality of interlayer insulating structures 103. In an embodiment, each of the plurality of sacrificial layers 101 may include a silicon nitride layer.

A slit 113 passing through the preliminary stacked body PST is formed.

Referring to FIG. 4B, the plurality of sacrificial layers 101 illustrated in FIG. 4A is removed through the slit 113, thereby forming a plurality of openings 121 between consecutive interlayer insulating structures 103 in the Z direction. The plurality of interlayer insulating structures 103 are supported by the plurality of insulating pillars 111 in this example.

Referring to FIG. 4C, a plurality of conductive layers 120 are formed in the plurality of openings 121, illustrated in FIG. 4B, through the slit 113. In an embodiment, forming the plurality of conductive layers 120 includes forming a metal barrier layer 123 along the surfaces of the interlayer insulating structures 103 and insulating pillars 111, which surfaces are adjacent to each of the openings 121, forming a metal layer 124 on the metal barrier layer 123, and removing sections of each metal barrier layer 123 and metal layer 124 inside the slit 113 such that the metal barrier layer 123 and the metal layer 124 are separated into a plurality of conductive layers 120. The metal barrier layer 123 may include a metal nitride layer such as titanium nitride, tantalum nitride, or molybdenum nitride. In an embodiment, the metal barrier layer 123 may include a dual layer of titanium and titanium nitride. The metal layer 124 may include tungsten, molybdenum, or the like. In an embodiment, the metal layer 124 may include tungsten formed on the metal barrier layer 123 including titanium nitride.

The plurality of conductive layers 120 are separated into a first gate array 125A and a second gate array 125B by the slit 113.

Each of the first gate array 125A and the second gate array 125B surrounds a corresponding insulating pillar 111 among the plurality of insulating pillars 111. The plurality of conductive layers 120 includes a plurality of first conductive layers of the first gate array 125A and a plurality of second conductive layer of the second gate array 125B. The plurality of interlayer insulating structures 103 are separated into a plurality of first interlayer insulating structures alternately arranged with the plurality of first conductive layers in the Z direction and a plurality of second interlayer insulating structure alternately arranged with the plurality of second conductive layers in the Z direction.

A stacked body ST is formed utilizing processes described with reference to FIG. 4A to FIG. 4C. The stacked body ST is partitioned by the slit 113, includes the plurality of conductive layers 120 alternately arranged with the plurality of interlayer insulating structures 103 in the Z direction and surrounds the corresponding insulating pillar 111 among the plurality of insulating pillars 111.

Referring to FIG. 4D, a gate separation structure 131 is formed by filling the slit 113 illustrated in FIG. 4C with various filling materials. In an embodiment, the filling materials may include an insulating material. In an embodiment, the filling materials may include an insulating material extending along the sidewall of the stacked body ST, a conductive material or a semiconductor material filling a central region of the slit opened by the insulating material, or a dual layer including a layer including the conductive material and a layer including the semiconductor material.

Holes 135 in the stacked body ST are opened by removing the plurality of insulating pillars 111 illustrated in FIG. 4C.

Referring to FIG. 4E, a porous layer 150 are formed along the sidewalls or inner surfaces of the metal barrier layer 123 and interlayer insulating structures 103 adjacent to each hole 135. The porous layer 150 has an etch selectivity relative to the plurality of interlayer insulating structures 103 illustrated in FIG. 4C. In an embodiment, the porous layer 150 includes a metal-organic framework.

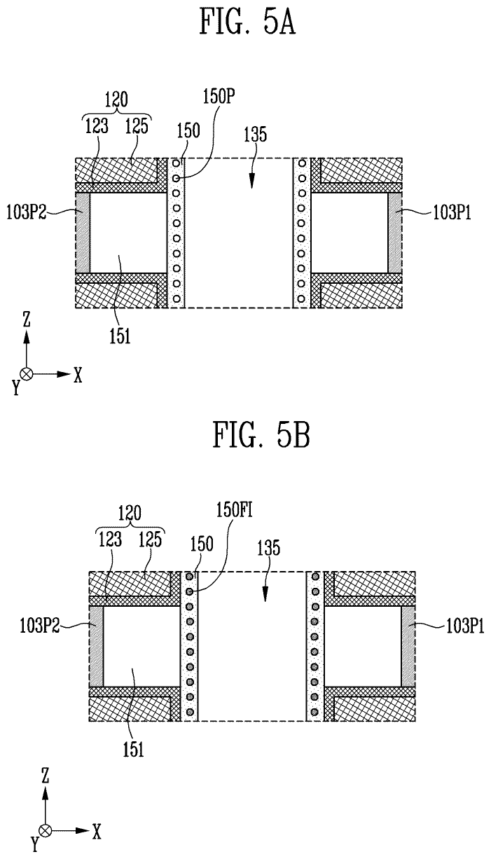

FIG. 5A and FIG. 5B are enlarged sectional views of the area AR1 of FIG. 4E.

Referring to FIG. 4E and FIG. 5A, sections of the plurality of interlayer insulating structures 103 adjacent to the porous layer 150 are removed by injecting an etching material through pores 150P of the porous layer 150. Each of the interlayer insulating structures 103 is separated into a first insulating pattern 103P1 and a second insulating pattern 103P2 with the porous layer 150 disposed between the first insulating pattern 103P1 and the second insulating pattern 103P2. A plurality of air gaps 151 is formed within each of the interlayer insulating structures 103. An air gap 151 is formed between the porous layer 150 and each first insulating pattern 103P1 and between the porous layer 150 and each second insulating pattern 103P2.

Alternatively, the area of each air gap 151 may be extended by completely removing the plurality of interlayer insulating structures 103 illustrated in FIG. 4D using the etching material injected through the pores 150P of the porous layer 150. The extended air gaps may be formed between the gate separation structure 131 and the porous layer 150. When the air gaps are extended, the plurality of conductive layers 120 are supported by the gate separation structure 131 and the porous layers 150.

Referring to FIG. 4F, a cell pillar 140 is formed in the central region of the hole 135 within the porous layer 150. A first cell pillar 140 surrounded by the plurality of first conductive layers 120 of the first gate array 125A and a second cell pillar 140 surrounded by the plurality of second conductive layers 120 of the second gate array 125B are formed.

In an embodiment, the cell pillar 140 is formed when the pores 150P are empty or unfilled, as illustrated in FIG. 5A.

Referring to FIG. 5B, in an embodiment, the pores 150P of the porous layer 150 illustrated in FIG. 5A are filled with an insulating material 150FI, before the cell pillar 140 is formed. In an embodiment, the insulating material 150FI may include various materials formed utilizing an atomic layer deposition (ALD) method. Depending on the type of the insulating material 150FI, the dielectric constant of the porous layer 150 may be controlled. In an embodiment, the insulating material 150FI may include an aluminum oxide layer or a hafnium oxide layer having a dielectric constant higher than a dielectric constant of silicon dioxide such that the porous layer 150 functions as a high dielectric blocking insulation layer.

Referring to FIG. 4F, forming the cell pillar 140 includes forming a blocking insulating layer 141 on the inner wall of the porous layer 150, forming a data storage layer 143 on the inner wall of the blocking insulating layer 141, forming a tunnel insulating layer 145 on the inner wall of the data storage layer 143, forming a channel layer 147 on the inner wall of the tunnel insulating layer 145, and filling a core insulating layer 149 in the space within the inner wall of the channel layer 147. In an embodiment, some of the core insulating layer 149 is removed from a region within the channel layer 147, and the region is filled with the capping pattern CAP as illustrated in FIG. 2B.

The blocking insulating layer 141 may include oxide such as silicon dioxide (SiO₂) and a high-dielectric insulating material having a dielectric constant higher than a dielectric constant of silicon dioxide. In an embodiment, the data storage layer 143 may include a charge trap insulating layer or an insulating layer including conductive nanodots. The tunnel insulating layer 145 may include oxide such as silicon dioxide (SiO₂). The channel layer 147 may include a semiconductor material such as silicon (Si), germanium (Ge), or a mixture thereof, which can be used as a channel region.

A subsequent process including forming the bit line connection structure BCC and bit lines BL, illustrated in FIG. 2A, may be performed.

According to an embodiment of the present disclosure, before the porous layer 150 and the cell pillar 140 are formed in the hole 135, the plurality of air gaps 151 are formed by an etching process through the hole 135. According to this process, compared to the example where air gaps are formed by an etching process through the slit after the cell pillar is formed, the injection of an etching material is not blocked by the cell pillar in an embodiment. Therefore, according to an embodiment, the difference between etch rates of the interlayer insulating structures depending on the distance from the slit may be reduced, and the uniformity of the air gaps 151 formed around the cell pillar 140 may be improved. Furthermore, during the etching process that forms the air gaps 151, damage to the cell pillar 140 can be reduced or prevented.

According to an embodiment of the present disclosure, capacitance between conductive layers may be reduced by arranging or aligning air gaps between consecutive conductive layers in a stack direction, thus improving operation speed of a semiconductor memory device.

According to an embodiment of the present disclosure, after a porous layer is formed, air gaps are formed by removing sections of interlayer insulating structures adjacent to the porous layer, and a cell pillar is formed within the hole, thus preventing damage to the cell pillar during formation of the air gaps.

Although detailed embodiments are described in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

What is claimed is:

1. A semiconductor memory device comprising:
a gate array including a plurality of conductive layers spaced apart from each other in a stack direction;
a channel pillar extending in the stack direction through the plurality of conductive layers;
a tunnel insulating layer between the channel pillar and the gate array;
a data storage layer between the tunnel insulating layer and the gate array;
a porous layer between the data storage layer and the gate array; and
an insulating molding structure including a plurality of interlayer insulating structures, the plurality of interlayer insulating structures alternately arranged with the plurality of conductive layers in the stack direction,
wherein a plurality of air gaps is formed within the plurality of interlayer insulating structures, respectively, and adjacent to the porous layer.

2. The semiconductor memory device according to claim 1, wherein the porous layer comprises a metal-organic framework (MOF) in which empty pores are formed.

3. The semiconductor memory device according to claim 1, wherein the porous layer comprises a metal-organic framework (MOF) including an insulating material within a plurality of pores formed in the MOF.

4. The semiconductor memory device according to claim 1, wherein the porous layer is spaced apart from the insulating molding structure by the plurality of air gaps.

5. The semiconductor memory device according to claim 1, further comprising a blocking insulating layer disposed between the porous layer and the data storage layer.

6. The semiconductor memory device according to claim 5, wherein pores of the porous layer are filled with an insulating material having a dielectric constant higher than a dielectric constant of the blocking insulating layer.

7. A semiconductor memory device comprising:
a first gate array including a plurality of first conductive layers spaced apart from each other in a stack direction;
a second gate array separated from the first gate array by a gate separation structure, the second gate array including a plurality of second conductive layers spaced apart from each other in the stack direction;
a plurality of first cell pillars extending in the stack direction through the plurality of first conductive layers;
a plurality of second cell pillars extending in the stack direction through the plurality of second conductive layers;
an insulating molding structure including a plurality of first interlayer insulating structures and a plurality of second interlayer insulating structures, the plurality of first interlayer insulating structures alternately arranged with the plurality of first conductive layers in the stack direction, the plurality of second interlayer insulating structures alternately arranged with the plurality of second conductive layers in the stack direction; and
a plurality of porous layers corresponding to the plurality of first cell pillars and the plurality of second cell pillars,
wherein an outer wall of each of the plurality of first cell pillars and the plurality of second cell pillars is surrounded by a corresponding porous layer of the plurality of porous layers, and
wherein a plurality of air gaps is formed within the insulating molding structure and adjacent to the plurality of porous layers.

8. The semiconductor memory device according to claim 7, wherein the plurality of air gaps are closer to the plurality of first cell pillars and the plurality of second cell pillars than to the gate separation structure.

9. The semiconductor memory device according to claim 7, wherein each of the plurality of first cell pillars and the plurality of second cell pillars comprises:
a channel layer surrounded by the corresponding porous layer;
a tunnel insulating layer between the channel layer and the corresponding porous layer; and
a data storage layer between the tunnel insulating layer and the corresponding porous layer.

10. The semiconductor memory device according to claim 9, wherein each of the plurality of first cell pillars and the plurality of second cell pillars further comprises a blocking insulating layer between the data storage layer and the corresponding porous layer.

11. The semiconductor memory device according to claim 10, wherein pores of each of the plurality of porous layers are filled with an insulating material having a dielectric constant higher than a dielectric constant of the blocking insulating layer.

12. The semiconductor memory device according to claim 7, wherein each of the plurality of porous layers comprises a metal-organic framework (MOF) in which empty pores are formed.

13. The semiconductor memory device according to claim 7, wherein each of the plurality of porous layer comprises a metal-organic framework (MOF) including an insulating material within a plurality of pores formed in the MOF.

14. The semiconductor memory device according to claim 7, wherein each of the plurality of first interlayer insulating structures and the plurality of second interlayer insulating structures comprises a first insulating pattern spaced apart from a second insulating pattern; and
wherein the plurality of first cell pillars or the plurality of second cell pillars are disposed between the first insulating pattern and the second insulating pattern.

15. A semiconductor memory device comprising:
a gate array including a plurality of conductive layers alternately stacked with a plurality of interlayer insulating structures in a stack direction;
a cell pillar extending through the gate array in the stack direction; and
a porous layer surrounding the cell pillar;
wherein an opening is formed between a first section of a first interlayer insulating structure of the plurality of interlayer insulating structures and a second section of the first interlayer insulating structure, the opening surrounding the porous layer disposed between the first section and the second section.

16. A method of manufacturing a semiconductor memory device, the method comprising:
forming a stacked body including a plurality of conductive layers alternately arranged with a plurality of interlayer insulating structures in a stack direction and surrounding an insulating pillar extending in the stack direction;
opening a hole in the stacked body by removing the insulating pillar;
forming a porous layer along a sidewall of the stacked body, the sidewall adjacent to the hole;
forming a plurality of air gaps within the plurality of interlayer insulating structures, respectively, and adjacent to the porous layer by removing, through the hole, sections of the plurality of interlayer insulating structures adjacent to the porous layer; and
forming a cell pillar in the hole and surrounded by the porous layer.

17. The method according to claim 16, wherein forming the stacked body comprises:
forming a preliminary stacked body including a plurality of sacrificial layers alternately arranged with the plurality of interlayer insulating structures in the stack direction, the preliminary stacked body surrounding the insulating pillar;
forming a slit through the preliminary stacked body;
forming a plurality of openings by removing the plurality of sacrificial layers through the slit; and
forming the plurality of conductive layers in the plurality of openings, respectively.

18. The method according to claim 16, wherein the porous layer comprises a metal-organic framework (MOF).

19. The method according to claim 16, further comprising, after the plurality of air gaps are formed, filling pores of the porous layer with an insulating material.

20. The method according to claim 19, wherein the insulating material has a dielectric constant higher than a dielectric constant of silicon dioxide.

21. The method according to claim 16, wherein forming the cell pillar comprises:
forming a blocking insulating layer on an inner wall of the porous layer;
forming a data storage layer on an inner wall of the blocking insulating layer;
forming a tunnel insulating layer on an inner wall of the data storage layer; and
forming a channel layer on an inner wall of the tunnel insulating layer.
